(19) United States
(12) Patent Application Publication
(10) Pub. No.: US 2024/0269795 A1
(43) Pub. Date: Aug. 15, 2024

(54) METHOD FOR MANUFACTURING A MICROMECHANICAL FASTENING ELEMENT, SHAPING TOOL FOR PRODUCING AN IMPRESSION OF THE MICROMECHANICAL FASTENING ELEMENT, AND MICROMECHANICAL FASTENING ELEMENT

(71) Applicant: Nivarox-FAR S.A., Le Locle (CH)

(72) Inventors: Frédéric HAEFELI, Tramelan (CH); Raphaël ZBINDEN, Bole (CH); Mickaël DUBIEF, Chavannes les Grands (FR); Raphaël THEURILLAT, Porrentruy (CH)

(73) Assignee: Nivarox-FAR S.A., Le Locle (CH)

(21) Appl. No.: 18/407,544

(22) Filed: Jan. 9, 2024

(30) Foreign Application Priority Data
Feb. 15, 2023 (EP) 23156908.8

(51) Int. Cl. B24B 5/36; B81B 1/00; B81C 99/00

(52) U.S. Cl. CPC B24B 5/36; B81B 1/006; B81C 99/001

(57) ABSTRACT

A method for manufacturing a fastening element including a step of producing a blank of the fastening element including a head and a shank connected to each other, followed by a step of forming an impression in the head, the forming step including an operation of machining the impression, carried out with a cutting member and an operation of matting a target surface of the impression carried out with a matting member.

### TECHNICAL FIELD OF THE INVENTION

The invention relates to the manufacture of micromechanical parts. The invention relates more particularly to a shaping tool for producing an impression of a micromechanical fastening element, a method for manufacturing the micromechanical fastening element and a micromechanical fastening element.

The present invention has an advantageous application in the field of watchmaking.

### Technological Background

In the field of micromechanics, in particular in the field of watchmaking, the aesthetic appearance of the mechanical parts of an assembly, such as a horological movement or watch case, is of great importance. In particular, the condition of the visible surfaces of the parts making up the assembly must be controlled.

To this end, certain flat surfaces are polished or decorated by removing material to give them a particular relief, such as guilloché, sunray finish, circular graining, etc.

However, the difficult-to-access surfaces of certain parts are left as they are after machining because of their very small dimensions. Such surfaces may consist for example of the back surfaces of impressions in micromechanical fastening elements, such as the back of screw slots.

Only the impression machining conditions are then decisive in defining the final surface condition of these impression back surfaces. In particular, this surface condition depends on the vibratory phenomena present during machining. As these phenomena are very difficult to control due to the very small dimensions of the cutting tool and the part to be machined, the back surface of the impression of a large number of machined parts does not have a surface condition that complies with manufacturing requirements.

The number of rejects is even higher when the fastening elements are intended for the high-end watchmaking industry, to the extent that their requirements in terms of finishing and surface quality are very high.

There is therefore a need to manufacture fastening elements where all visible surfaces have a controlled surface condition to meet the most stringent requirements.

### SUMMARY OF THE INVENTION

The invention resolves the aforementioned disadvantages by proposing a solution for producing a micromechanical fastening element, such as a screw or other tightening element, comprising an impression designed to cooperate with a tightening tool for applying a tightening torque, while controlling the condition of the visible surfaces of the impression.

Furthermore, one of the purposes of the invention is to control the cost of manufacturing the fastening element.

To this end, one aspect of the present invention relates to a method for manufacturing a micromechanical fastening element comprising a step of producing a blank of the fastening element comprising a head and a shank connected to each other, followed by a step of forming an impression in the head. The step of forming an impression comprises a machining operation of the impression, carried out with a cutting member, and an operation of matting a target surface of the impression, carried out with a matting member.

Advantageously, the matting step allows to modify the condition of the target surface after machining so that it meets the manufacturing requirements. In particular, this matting step allows, during manufacture of the fastening element, to improve the condition of the target surface, that is to say to minimise the geometric defects of said surface on a micrometric scale, by plastic deformation of the material under the effect of a local pressure generated by the matting member.

In particular embodiments, the invention may further include one or more of the following features, taken alone or in any technically possible combination.

In particular implementations, the step of forming an impression in the head is carried out with a single shaping tool on which the cutting member and the matting member are arranged.

In particular implementations, when carrying out the entire impression forming step, the fastening element is held in the same position, only the shaping tool being moved.

In particular implementations, the matted target surface is a back surface of the impression, the matting operation being carried out so that said back surface has a Ra comprised between 0.01 μm and 0.1 μm at the end of the forming step.

In particular implementations, when carrying out the machining and matting operations, the shaping tool is driven in different directions of rotation, the cutting member and the matting member being arranged on the same disc of the shaping tool.

In particular implementations, during the machining and matting operations, the blank is machined by a cutting member and matted by a matting member, each formed by a disc of the shaping tool, said discs being parallel and coaxial.

In particular implementations, the matting operation is carried out by a plurality of successive passes of the matting member over the target surface, each pass being carried out to a pass depth comprised between 0.1 μm and 2 μm or between 0.5 μm and 1.5 μm.

According to another object, the present invention relates to a shaping tool for producing an impression of a micromechanical fastening element. The shaping tool is advantageously adapted to carry out the aforementioned manufacturing method.

The forming tool comprises a body extending along a longitudinal axis about which the tool is intended to be rotated. The forming tool further comprises, arranged at a longitudinal end of the body, a cutting member comprising a cutting edge intended to remove material from a fastening element so as to generate an impression when the tool is rotated, and a matting member comprising an active surface intended for matting a target surface of the impression when the tool is rotated.

In particular embodiments, the cutting and matting members are in the form of a single disc configured so that when the tool is driven in a first direction of rotation, the cutting member is active and the matting member is inactive, and when it is driven in a second direction of rotation opposite to the first direction of rotation, the cutting member is inactive and the matting member is active.

In particular embodiments, the disc includes a plurality of regularly distributed peripheral teeth, each tooth comprising at its vertex a relief face forming the active surface of the matting member, said relief face further defining, with a leading face of each tooth, the cutting edge of the cutting member.

In particular embodiments, each of the cutting and matting members is in the form of a disc, the discs being arranged in parallel and coaxially, the cutting edges and the active surface being respectively arranged at the periphery of said discs.

In particular embodiments, the active surface of the matting member has a circular cross-section.

In particular embodiments, the active surface of the matting member has a polygonal cross-section, comprising segments joined together by rounded vertices.

In particular embodiments, the segments have a concave curvature.

Another aspect of the invention relates to a micromechanical fastening element made of a metallic material and preferably by the implementation of the manufacturing method according to the invention, comprising a shank connected to a head. The head comprises an impression extending from an opening to a back surface, said fastening element being characterised in that the back surface has a Ra comprised between 0.01 μm and 0.1 μm.

In particular embodiments, the impression is intended to cooperate with a tightening tool for transmitting a torque, the shank comprising a thread.

### BRIEF DESCRIPTION OF THE FIGURES

Other features and advantages of the invention will become apparent upon reading the following detailed description given as a non-limiting example, with reference to the appended drawings wherein:

FIG. 1 schematically shows a plan view of a shaping tool according to a first embodiment of the invention;

FIG. 2 shows a cross-sectional view along the cutting axis A-A of a cutting member of the shaping tool of FIG. 1;

FIG. 3 shows a cross-sectional view along the cutting axis B-B of a matting member of the shaping tool of FIG. 1;

FIG. 4 schematically shows a plan view of a shaping tool according to a second embodiment of the invention.

Note that the figures are not necessarily drawn to scale for reasons of clarity.

### DETAILED DESCRIPTION OF THE INVENTION

A first aspect of the present invention relates to a method for manufacturing a micromechanical fastening element, for example a screw, and preferably a watch screw, intended to be visible to a user. This micromechanical fastening element is made of a metallic material, such as steel, titanium, etc., and is preferably intended for the watchmaking field, but can be generally adapted for use in all micromechanical fields.

The method includes a step of producing a blank of the fastening element comprising a head and a shank connected to each other, followed by a step of forming an impression in the head.

This impression extends from an opening to a back surface and is advantageously designed to receive a head of a tightening tool, such as a screwdriver, in order to apply a torque to the fastening element. In this case, the step of producing the blank may include a threading operation to produce a thread on the shank of the blank. Alternatively, the impression may be purely decorative.

In all cases, the head of the fastening element, and hence the impression, is intended to be visible to a user. The impression may be of any suitable shape, for example cruciform, polygonal cross-section, etc., or in the shape of a straight slot.

Advantageously, the step of forming the impression comprises both an operation of machining the impression carried out with a cutting member 11 and an operation of matting a target surface of the impression carried out with a matting member 12. The target surface of the impression is intended to be visible to a user and preferably constitutes the back of the impression.

Thanks to these features, the surfaces of the impression, and in particular the back of the impression, have a controlled surface condition, which is for example polished, which allows it to meet the most stringent requirements in terms of appearance. Indeed, the matting operation is carried out so that said back surface has a Ra comprised between 0.01 μm and 0.1 μm, preferably between 0.02 μm and 0.05 μm, at the end of the impression formation step.

It also follows from these features that, thanks to the method according to the invention, it is possible to produce micromechanical fastening elements industrially with excellent repeatability, which allows to greatly reduce or eliminate manufacturing rejects. Furthermore, the fact that the machining and matting operations are carried out in the same step of the method allows to optimise the manufacturing time for a fastening element and to control its costs.

The machining operation is carried out so that the impression has a depth comprised between 0.05 and 0.5 mm, for example between 100 μm and 200 μm, such as 170 μm, and to this end can be carried out in one or more passes of the cutting member 11. In particular, the machining operation can be carried out by a blank pass followed by a finishing pass, the latter being a few micrometres deep, for example 2 μm.

The matting operation can be carried out by a plurality of successive passes of the matting member 12 over the target surface, for example three passes, each pass being carried out to a pass depth comprised between 0.1 μm and 2 μm, and preferably between 0.5 μm and 1.5 μm, for example 1 μm. Thus, the material of the target surface is cold-worked by the matting member 12, which substantially allows to flatten the target surface on a micrometric or submicrometric scale and therefore improves its surface condition.

Advantageously, the step of forming the impression can be carried out with a single shaping tool 10 described below in detail according to another aspect of the present invention, on which the cutting member 11 and the matting member 12 are arranged. Such a shaping tool 10 is intended to be fixed to a tool holder of a machining centre so as to be rotated in order to make the impression of the fastening element.

The method can include a finishing step wherein the outer surface of the head, that is to say the surface delimiting the head with the exception of the surface of the impression, is polished.

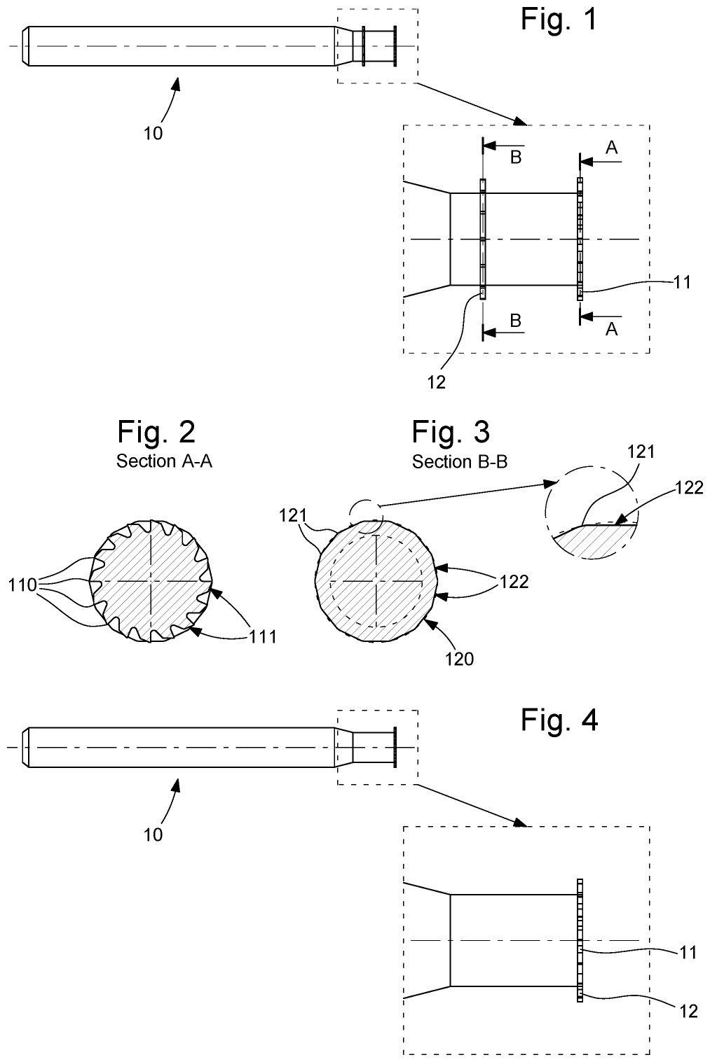

As can be seen in FIG. 1, the shaping tool 10 comprises a body, for example in the form of a stake, extending along a longitudinal axis constituting the axis of rotation of the tool. The cutting member 11 and the matting member 12 are arranged at the free end of the body. The cutting member 11 comprises a cutting edge 110 intended to remove material from the head of the fastening element so as to form the impression when the tool is rotated. The matting member 12 comprises an active surface 120 for matting the target surface of the impression when the tool is rotated.

Advantageously, during all the operations in the impression forming step, the fastening element is held in the same position, only the shaping tool 10 being moved to perform the various passes. This improves compliance with machining tolerances.

In a first embodiment, the cutting member 11 and the matting member 12 are each formed by a disc of the shaping tool 10, said discs being parallel and coaxial. Such a design of the shaping tool 10 is shown in FIG. 1. As can be seen in FIGS. 2 and 3, the cutting edges 110 and the active surface 120 are respectively arranged at the periphery of said discs. By way of example, the discs may have a diameter of a few millimetres, for example 4 mm.

As can be seen in FIG. 2, the cutting member 11 has the shape of a circular milling-cutter. This cutting member 11 includes a plurality of peripheral teeth, for example sixteen teeth, regularly distributed, each tooth comprising at its vertex a relief face 111. Together with a leading face of each tooth, the relief faces 111 define the cutting edge 110 of the cutting member 11.

In this embodiment, the matting member 12 can have a cross-section of substantially polygonal shape, as illustrated in FIG. 3, comprising segments 122 joined together by rounded vertices 121. In the preferred example, the matting member 12 includes fourteen vertices 121, the radius of which is a few tenths of a millimetres. The segments 122 may be straight or may have a concave curvature dimensioned so that it has a maximum deviation from a theoretical circle passing through the vertices 121 of a few hundredths of a millimetres, as shown in the detail view in FIG. 3.

Alternatively, in embodiments of the invention not shown in the figures, the active surface 120 of the matting member 12 may have a circular cross-section.

In a second embodiment of the invention shown in FIG. 4, the cutting member 11 and the matting member 12 are in the form of the same disc. This disc has substantially the same shape as the disc of the first embodiment constituting the cutting member 11 shown in FIG. 2. This disc is configured so that when the tool is driven in a first direction of rotation, the cutting member 11 is active and the matting member 12 is inactive, and when it is driven in a second direction of rotation opposite to the first direction of rotation, the cutting member 11 is inactive and the matting member 12 is active. More precisely, the relief face 111 forms the active surface 120 of the matting member 12.

More generally, it should be noted that the implementations and embodiments considered above have been described by way of non-limiting examples, and that other variants are therefore considered.

1. A method for manufacturing a micromechanical fastening element, wherein the method comprises a step of producing a blank of the fastening element comprising a head and a shank connected to each other, followed by a step of forming an impression in the head, said forming step comprising an operation of machining the impression, carried out with a cutting member, and an operation of matting a target surface of the impression, carried out with a matting member.

2. The manufacturing method according to claim 1, wherein the step of forming an impression in the head is carried out with a single shaping tool on which the cutting member and the matting member are arranged.

3. The method according to claim 2, wherein when carrying out the entire impression forming step, the fastening element is held in the same position, only the shaping tool being moved.

4. The method according to claim 1, wherein the matted target surface is a back surface of the impression, the matting operation being carried out so that said back surface has a Ra comprised between 0.01 μm and 0.1 μm at the end of the forming step.

5. The method according to claim 2, wherein, when carrying out the machining and matting operations, the shaping tool is driven in different directions of rotation, the cutting member and the matting member being arranged on the same disc of the shaping tool.

6. The method according to claim 2, wherein during the machining and matting operations, the blank is machined by a cutting member and matted by a matting member each formed by a disc of the shaping tool, said discs being parallel and coaxial.

7. The method according to claim 1, wherein the matting operation is carried out by a plurality of successive passes of the matting member over the target surface, each pass being carried out to a pass depth comprised between 0.1 μm and 2 μm or between 0.5 μm and 1.5 μm.

8. A shaping tool for producing an impression of a micromechanical fastening element, comprising a body extending along a longitudinal axis about which the tool is intended to be rotated, wherein the tool being characterised in that it includes, arranged at a longitudinal end of the body, a cutting member comprising a cutting edge intended to remove material from a fastening element so as to generate an impression when the tool is rotated, and a matting member comprising an active surface intended for matting a target surface of the impression when the tool is rotated.

9. The shaping tool according to claim 8, wherein the cutting and matting members are in the form of the same disc configured so that when the tool is driven in a first direction of rotation, the cutting member is active and the matting member is inactive, and when it is driven in a second direction of rotation opposite to the first direction of rotation, the cutting member is inactive and the matting member is active.

10. The shaping tool according to claim 9, wherein the disc includes a plurality of regularly distributed peripheral teeth, each tooth comprising at its vertex a relief face forming the active surface of the matting member, said relief face further defining, with a leading face of each tooth, the cutting edge of the cutting member.

11. The shaping tool according to claim 8, wherein each of the cutting and matting members is in the form of a disc, the discs being arranged in parallel and coaxially, the cutting edges and the active surface being respectively arranged at the periphery of said discs.

12. The shaping tool according to claim 11, wherein the active surface of the matting member has a circular cross-section.

13. The shaping tool according to claim 12, wherein the active surface of the matting member has a polygonal cross-section, comprising segments joined together by rounded vertices.

14. The shaping tool according to claim 12, wherein the segments have a concave curvature.

15. A micromechanical fastening element made of a metallic material comprising a shank connected to a head, said head comprising an impression extending from an opening to a back surface, wherein the back surface has a Ra comprised between 0.01 μm and 0.1 μm.

16. The fastening element according to claim 15, wherein the impression is intended to cooperate with a tightening tool for transmitting a torque, the shank comprising a thread.
